(19) United States
(12) Patent Application Publication
(10) Pub. No.: US 2026/0218409 A1
(43) Pub. Date: Jul. 30, 2026

(54) METHOD AND SYSTEM OF GROWING AND USING CESIUM LITHIUM BORATE CRYSTALS

(71) Applicant: KLA Corporation, Milpitas, CA (US)

(72) Inventors: John Fielden, Los Altos, CA (US); Yung-Ho Alex Chuang, Cupertino, CA (US)

(21) Appl. No.: 19/413,832

(22) Filed: Dec. 9, 2025

Related U.S. Application Data
(60) Provisional application No. 63/750,290, filed on Jan. 28, 2025.

(51) Int. Cl. C30B 9/12; C30B 29/22; H01S 3/00; H01S 3/16; G01N 21/01

(52) U.S. Cl. CPC C30B 9/12; C30B 29/22; H01S 3/0092; H01S 3/1666; G01N 21/01; G01N 2201/06113

(57) ABSTRACT

A method and system for growing a cesium lithium borate (CsLiB₆O₁₀) crystal is provided. Lasers and characterization systems incorporating a cesium lithium borate crystal grown according to the method disclosed herein are also provided. The method includes growing a crystal from a melt that contains chloride (Cl⁻) ions. These crystals have lower defect density and contain fewer OH groups and/or less water than crystals grown by conventional techniques and so are suitable for use at high powers and short deep UV wavelengths. A frequency conversion apparatus and an optical system containing a frequency conversion apparatus are also provided.

### CROSS-REFERENCE TO RELATED APPLICATIONS

The present application claims the benefit of U.S. Provisional Patent Application No. 63/750,290, filed on January 28, 2025, which is incorporated herein by reference in the entirety.

### TECHNICAL FIELD

The present disclosure relates to crystal growth and, more particularly, to growth of a single-crystal material, cesium lithium borate (CsLiB₆O₁₀, CLBO), suitable for use in nonlinear optical components such as for frequency conversion in deep ultraviolet (DUV) lasers. Such lasers are suitable for use in, for example, metrology and inspection systems in semiconductor manufacturing, including those used to inspect and/or measure photomasks, reticles, and semiconductor wafers.

### BACKGROUND

As dimensions of semiconductor devices shrink, the size of the smallest particle or pattern defect that can cause a device to fail also shrinks. Hence, a need arises for detecting smaller particles and defects on patterned and unpatterned semiconductor wafers and reticles. The intensity of light scattered by particles smaller than the wavelength of that light generally scales as a high power of the dimensions of that particle. For example, the total scattered intensity of light from an isolated, small, spherical particle scales proportional to the sixth power of the diameter of the sphere and inversely proportional to the fourth power of the wavelength. Because of the increased intensity of the scattered light, shorter wavelengths will generally provide better sensitivity for detecting small particles and defects than longer wavelengths. Therefore, high speed inspection in the semiconductor industry is commonly performed in machines utilizing ultraviolet (UV) light. One method of generating UV light involves using nonlinear crystals transparent in the UV to frequency convert from longer wavelengths to UV wavelengths.

Few optical crystals exist that are transparent and have a high damage threshold in the DUV (wavelengths in the approximate range of 185-300 nm). Furthermore, frequency conversion preferably requires that the crystal has a useful nonlinear coefficient (e.g., d_{eff} larger than about 0.5 pm V⁻¹) and sufficient birefringence to enable phase matching of the input and output wavelengths. For these reasons, CLBO has been used as a nonlinear crystal for generating DUV light by frequency doubling and frequency summing of light with wavelengths in the visible and near infrared regions of the electromagnetic spectrum.

CLBO has some disadvantages which have limited its use for generating DUV light at high power levels (such as powers greater than about 100 mW) and at wavelengths shorter than about 250 nm. CLBO is hygroscopic, so it must be always protected from exposure to water or humidity, including during handling, shipping, storage, processing and use. Water and OH groups within CLBO can strongly absorb DUV light, especially at the shortest wavelengths, which can result in damage to the crystal and a short operating lifetime. Furthermore, this sensitivity to water may be enhanced when the crystal contains many defects or impurities.

It is not simple to grow high quality CLBO crystals with few impurities or defects. Stoichiometric molten CLBO has very high viscosity, which makes it difficult to thoroughly mix the melt and maintain uniform composition throughout the melt during crystal growth. Furthermore, crystals tend to grow quickly from a stoichiometric melt which can result in more defects in the crystal. Very precise control of the temperature may be necessary to achieve good crystal quality. Mori et al., in Applied Physics Letters 67 (13), 1818 (1995), described growing a crystal from a boron-deficient solution, which has a lower viscosity than a stoichiometric melt. However, when a crystal grows from a boron-deficient solution, the crystal will remove boron from the solution faster relative to its concentration than it removes cesium and lithium causing the local composition to deviate further from stoichiometry. Although the viscosity of the boron-deficient solution is lower than that of the stoichiometric melt, it is still high. Furthermore, since the cations (Cs⁺ and Li⁺) in the solution must be balanced by anions (borate and OH⁻), the OH⁻ concentration relative to the borate concentration must increase as boron is removed. This can result in more OH being incorporated into the crystal, which is highly undesirable for high-power DUV generation as described above.

Therefore, a CLBO growth method to overcome some or all of the above-mentioned limitations is desirable.

### SUMMARY

A method of manufacturing a cesium lithium borate crystal is disclosed, in accordance with one or more embodiments of the disclosure. In embodiments, the method includes forming a material containing cesium, lithium, boron, oxygen, and chlorine. In embodiments, the method includes heating the material to form a melt. In embodiments, the method includes controlling the melt temperature. In embodiments, the method includes lowering a seed crystal into the melt. In embodiments, the method includes adjusting the melt temperature to grow the crystal. In embodiments, during growth, the seed crystal is maintained at about 840 °C to 860 °C. In embodiments, the chloride source comprises lithium chloride or cesium chloride present in an amount of about 0.1 to 10 mole percent. In embodiments, the melt contains approximately 5 to 6 mole percent cesium and 27 to 37 mole percent boron. In embodiments, the starting material is heated to a temperature in the range of approximately 800 °C to 950 °C. In embodiments, crystal growth is carried out by a top-seeded solution method, a flux method, or a melt method.

A crystal growth system for growing a cesium lithium borate crystal is disclosed, in accordance with one or more embodiments of the disclosure. In embodiments, the system comprises a crucible containing a melt of cesium, lithium, boron, oxygen, and chloride ions. In embodiments, the system comprises a seed holder configured to position a seed crystal within the melt. In embodiments, the system comprises heating elements configured to control the temperatures of both the melt and the seed crystal. In embodiments, the system comprises a controller configured to maintain the melt above 850 °C and to maintain the seed crystal at about 840 °C to 860 °C during crystal growth.

A cesium lithium borate single crystal is disclosed, in accordance with one or more embodiments of the disclosure. In embodiments, the single crystal is grown from a melt comprising cesium, lithium, boron, oxygen, and about 0.1 to 10 mole percent chloride ions. In embodiments, the single crystal exhibits hydroxyl impurity content that is lower than that of crystals grown from melts lacking chloride. In embodiments, the single crystal exhibits crystallographic defect density that is lower than that of crystals grown from melts lacking chloride.

A frequency conversion apparatus containing a cesium lithium borate crystal is disclosed, in accordance with one or more embodiments of the disclosure. In embodiments, the frequency conversion apparatus comprises the cesium lithium borate single crystal manufactured by the disclosed method.

A laser configured to generate ultraviolet light is disclosed, in accordance with one or more embodiments of the disclosure. In embodiments, the laser is configured to generate ultraviolet light in a wavelength range of about 185 nm to 300 nm. In embodiments, the laser comprises one or more frequency conversion apparatuses containing a cesium lithium borate crystal manufactured by the disclosed method.

A system for inspecting or measuring a sample is disclosed, in accordance with one or more embodiments of the disclosure. In embodiments, the system comprises an illumination source configured to generate light in a wavelength range of about 185 nm to 300 nm. In embodiments, the system comprises an optical subsystem configured to direct the illumination onto a sample and to collect reflected, scattered, or transmitted light. In embodiments, the system comprises a sensor configured to detect the collected light. In embodiments, the system comprises a controller configured to analyze sensor data. In embodiments, the illumination source includes the disclosed ultraviolet laser.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures.

FIG. 1 illustrates a simplified block diagram depicting an optical characterization system, in accordance with one or more embodiments of the present disclosure.

FIG. 2 illustrates a simplified block diagram depicting a DUV laser that generates DUV radiation by frequency conversion of a longer wavelength laser, wherein at least one frequency conversion stage includes a CLBO crystal, in accordance with one or more embodiments of the disclosure; and

FIG. 3 illustrates a simplified schematic diagram depicting a furnace for growing CLBO, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

The present disclosure relates to an improvement in growth quality and growth rate for CLBO crystals for optical systems such as semiconductor inspection systems. The present disclosure generally relates to a method of growing CLBO with a melt or solution method comprising chloride ions (Cl⁻) as a component of the melt or solution, in accordance with one or more embodiments of the present disclosure. These CLBO crystals may be grown with the Kyropoulos method, high-temperature solution top-seeding method, seeded-hydrothermal method, or other seeded or non-seeded flux, solution, or melt method. Embodiments of the present disclosure are related to U.S. Patent Publication No. 20250084557A1, published on March 13, 2025, by Chuang et al., which is incorporated herein by reference in the entirety.

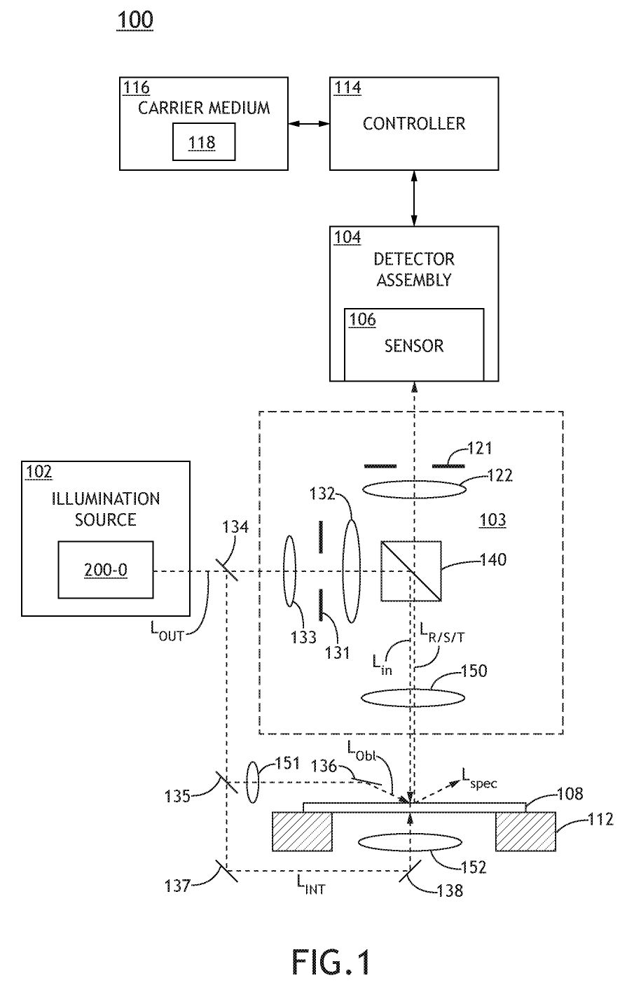

FIG. 1 illustrates a simplified block diagram of a characterization system 100, in accordance with one or more embodiments of the present disclosure. The characterization system 100 may be configured to inspect or measure a sample 108. The characterization system 100 may comprise an inspection system or a metrology system. Characterization system 100 may also be configured to cut, drill, or ablate material from sample 108, or to expose a pattern onto photoresist on sample 108.

Sample 108 may include any sample known in the art such as, but not limited to, a wafer, reticle, photomask, or the like. In one embodiment, the sample 108 is disposed on a stage assembly 112 to facilitate movement of the sample 108. The stage assembly 112 may include any stage assembly known in the art including, but not limited to, an X-Y stage, an R-θ stage, and the like. In another embodiment, the stage assembly 112 is capable of adjusting the height of the sample 108 during inspection to maintain focus on the sample 108. In yet another embodiment, a lens such as objective lens 150 may be moved up and down during inspection to maintain focus on the sample 108.

Characterization system 100 includes an illumination source 102 that incorporates a laser 200-0 that generates output light L_{OUT} having an output frequency ω_{OUT} with a corresponding wavelength in a range between approximately 185 nm and approximately 300 nm. Illumination source 102 may include additional light sources such as a laser operating at a longer or shorter wavelength or a broadband light source. Laser 200-0 may incorporate a CLBO crystal that is grown as disclosed herein. Characterization system 100 includes one or more optical components such as beam splitters, mirrors, lenses, apertures and waveplates that are configured to condition and direct light L_{OUT} to sample 108, and can be configured from one or more of strontium tetraborate, calcium fluoride, fused silica and other DUV-transmissive materials. The optical components may be configured to illuminate an area, a line, or one or more spots on sample 108. In one embodiment, beam splitter or mirror 134, mirrors 137 and 138 and lens 152 are configured to illuminate sample 108 from below so as to enable inspection or measurement of sample 108 by transmitting light L_{INT} through the sample. In another embodiment, beam splitters or mirrors 134 and 135, mirror 136 and lens 151 are configured to illuminate sample 108 with light at an oblique angle of incidence L_{Obl}, for example at an angle of incidence greater than about 60° relative to a normal to the sample surface. In this embodiment, the specularly reflected light L_{Spec} may be blocked or discarded rather than collected. In yet another embodiment, optics 103 are collectively configured to direct illumination light L_{IN} to the top surface of sample 108.

When sample 108 is illuminated in one or more of the above-described modes, optics 103 are also configured to collect light L_{R/S/T} reflected, scattered, diffracted, transmitted and/or emitted from the sample 108 and direct and focus the light L_{R/S/T} to sensor 106 of a detector assembly 104. It is noted herein that sensor 106 and the detector assembly 104 may include any sensor 106 known in the art. The sensor may include, but is not limited to, a charge-coupled device (CCD) detector, a complementary metal oxide semiconductor (CMOS) detector, a time-delay integration (TDI) detector, a photomultiplier tube (PMT), an avalanche photodiode (APD), a line sensor, an electron-bombarded line sensor, or the like. Detector assembly 104 is communicatively coupled to a controller 114.

Controller 114 is configured to store and/or analyze data from detector assembly 104 under control of program instructions 118 stored on carrier medium 116. Controller 114 may be further configured to control other elements of characterization system 100 such as stage 112, illumination source 102 and optics 103.

In one embodiment, the optics 103 includes an illumination tube lens 132. The illumination tube lens 132 may be configured to image an illumination pupil aperture 131 to a pupil within an objective lens 150. For example, the illumination tube lens 132 may be configured such that the illumination pupil aperture 131 and the pupil within the objective lens 150 are conjugate to one another. In one embodiment, the illumination pupil aperture 131 may be configurable by switching different apertures into the location of illumination pupil aperture 131. In another embodiment, the illumination pupil aperture 131 may be configurable by adjusting a diameter or shape of the opening of the illumination pupil aperture 131. In this regard, the sample 108 may be illuminated by different ranges of angles depending on the characterization (e.g., measurement or inspection) being performed under control of the controller 114. Illumination pupil aperture 131 may also include a polarizing element to control the polarization state of the illumination light L_{IN}.

In one embodiment, the one or more optical elements 103 include a collection tube lens 122. For example, the collection tube lens 122 may be configured to image the pupil within the objective lens 150 to a collection pupil aperture 121. For instance, the collection tube lens 122 may be configured such that the collection pupil aperture 121 and the pupil within the objective lens 150 are conjugate to one another. In one embodiment, the collection pupil aperture 121 may be configurable by switching different apertures into the location of collection pupil aperture 121. In another embodiment, the collection pupil aperture 121 may be configurable by adjusting a diameter or shape of the opening of collection pupil aperture 121. In this regard, different ranges of angles of illumination reflected or scattered from the sample 108 may be directed to detector assembly 104 under control of the controller 114. Collection pupil aperture 121 may also include a polarizing element so that a specific polarization of light L_{R/S/T} can be selected for transmission to sensor 106. In another embodiment, the illumination pupil aperture 131 and/or the collection pupil aperture 121 may include a programmable aperture. The optics 103 may include any number and type of illumination optic 133. The optics 103 may include a beamsplitter 140.

The various optical elements and operating modes depicted in FIG. 1 are merely to illustrate how laser 200-0 may be used in characterization system 100 and are not intended to limit the scope of the present disclosure. A practical characterization system 100 may implement a subset or a superset of the modes and optics depicted in FIG. 1. Additional optical elements and subsystems may be incorporated as needed for a specific application.

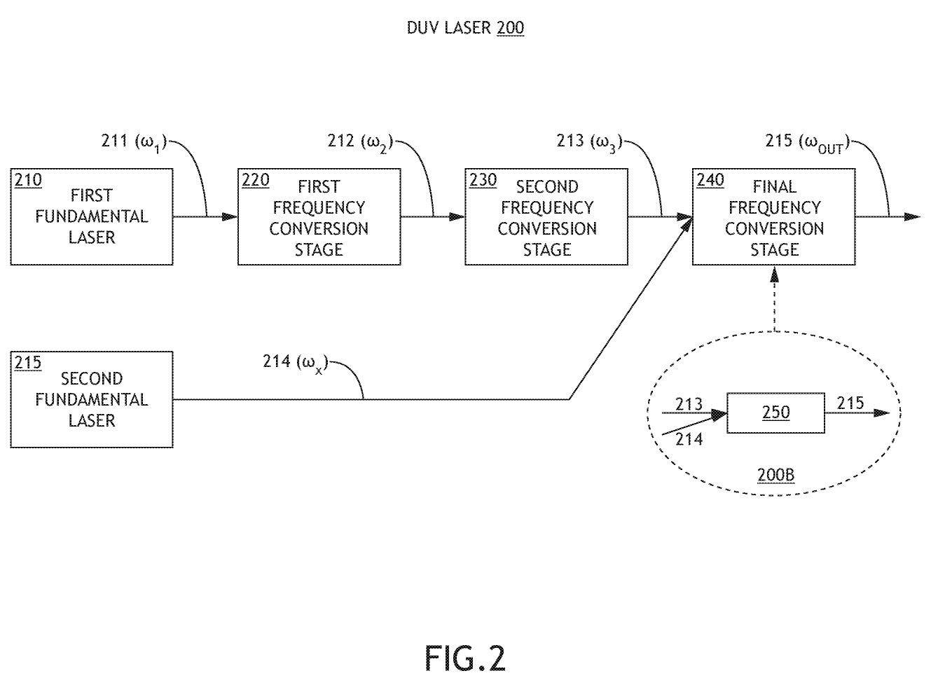

FIG. 2 illustrates a simplified schematic view of a DUV laser 200 incorporating a CLBO crystal in at least one frequency conversion stage, in accordance with one or more embodiments of the present disclosure. In this embodiment, first fundamental laser 210 generates a first fundamental light 211 having a first fundamental frequency ω₁.

First frequency conversion stage 220 converts the first fundamental light 211 to a second light 212 having a second frequency ω₂. First frequency conversion stage may include any frequency conversion technique known in the art including, but not limited to, harmonic generation (such as generating a 2^{nd} or higher harmonic of the first fundamental frequency), frequency summation, or optical parametric conversion. Hence, second frequency ω₂ may be higher or lower than first fundamental frequency ω₁.

Second frequency conversion stage 230 converts the second light 212 to a third light 213 having a third frequency ω₃. Third frequency conversion stage may include any frequency conversion technique known in the art including, but not limited to, harmonic generation (such as generating a 2^{nd} or higher harmonic of the second frequency), frequency summation, frequency differencing, or optical parametric conversion. Hence, third frequency ω₃ may be higher or lower than second frequency ω₂.

Final frequency conversion stage 240 converts the third light 213 to an output light 215 having an output frequency ω_{OUT}. In this embodiment, final frequency conversion stage 240 is configured to perform summation of the third light 213 with a second fundamental light 214 having a second fundamental frequency ωₓ generated by second fundamental laser 215. In alternative embodiments (not shown), DUV laser 200 may be configured so that final frequency conversion stage 240 sums third light with a portion of one of the first fundamental light and the second light to generate output light 215 having an output frequency ω_{OUT} equal to ω₁ + ω₃ or equal to ω₂ + ω₃ respectively. In these alternative embodiments second fundamental laser 215 is not needed and may be omitted. In another alternative embodiment, final frequency conversion stage 240 may include harmonic generation (such as generating a 2^{nd} or higher harmonic of the third frequency).

As illustrated in callout 200B, in final frequency conversion stage 240, third light 213 and second fundamental light 214 enter a nonlinear optical crystal 250 substantially colinearly to one another, such as at a relative angle of less than about 5° to one another. Nonlinear crystal 250 comprises a CLBO crystal grown as disclosed herein. Note that CLBO crystals grown as disclosed herein are suitable for use in many different frequency conversion schemes. Other frequency conversion stages depicted in exemplary DUV laser 200, such as the first frequency conversion stage 220 or the second frequency conversion stage 230, may include a CLBO crystal grown as disclosed herein. Note also that a DUV laser incorporating a CLBO crystal grown as disclosed herein may have more or fewer frequency conversion stages than are depicted in FIG. 2. Further note that a CLBO crystal grown as disclosed herein may be used in a laser that includes only a first fundamental laser, or it may be used in a laser with more than one fundamental laser. FIG. 2 and DUV laser 200 are merely intended as an illustration of a typical laser that could advantageously incorporate one more CLBO crystals grown as disclosed herein. FIG. 2 and DUV laser 200 are not intended to limit the scope of where these CLBO crystals may be used. CLBO crystals grown as disclosed herein may be used in any frequency conversion technique known in the art including, but not limited to, harmonic generation (such as generating a 2^{nd} or higher harmonic of the first fundamental frequency), frequency summation, or optical parametric conversion (such as in an optical parametric oscillator or an optical parametric amplifier). Other examples of DUV lasers that can advantageously incorporate a CLBO crystal grown as disclosed herein are described in U.S. Patent Application No. 19/379,045, filed on November 11, 2025, which is incorporated herein by reference in the entirety.

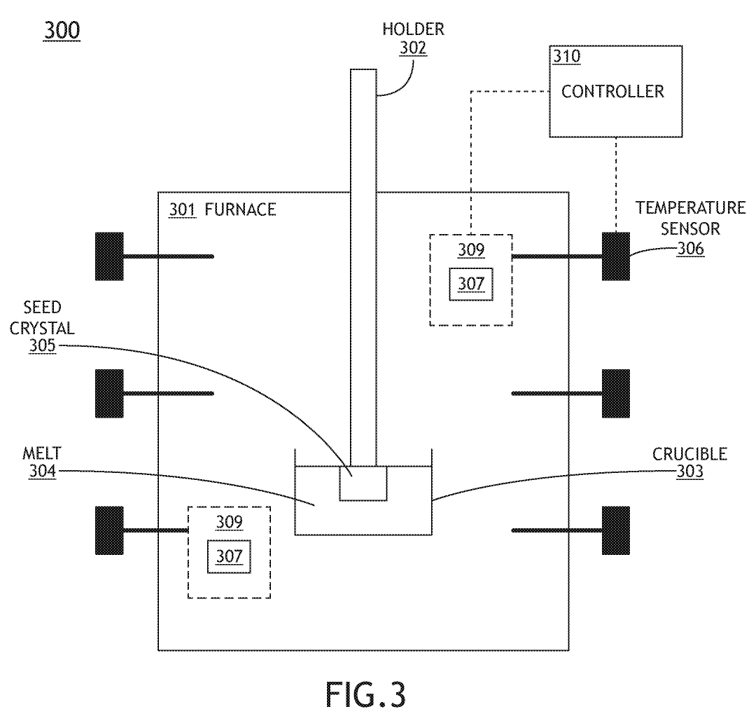

FIG.3 illustrates system 300 for growing cesium lithium borate crystals from a seed 305 using the top seeded approach, in accordance with one or more embodiments of the present disclosure. Note that FIG. 3 is not drawn to scale but is intended to illustrate key aspects of the system 300 suitable for growing crystals by the method disclosed herein. In embodiments, the system 300 includes a heating furnace 301 (e.g., resistance heating furnace). The heating furnace 301 may include one or more heating zones 309. The furnace 301 may include a crucible 303 (e.g., platinum crucible). The crucible 303 may have a diameter of about 150 mm and a height of about 150 mm. The crucible 303 can be larger or smaller depending on the required size of the crystals to be grown. In embodiments, the crucible 303 is approximately twice the diameter of the desired final crystal size. The crucible may be configured to contain a melt comprising cesium, lithium, boron, oxygen, and between about 0.1 mole-percent and about 10 mole-percent chloride ions. The crucible may be configured to contain a melt comprising approximately between 5 and 6 mole-percent Cs and approximately between 27 and 37 mole-percent B. A seed crystal 305 is fixed to a seed holder 302 (e.g., alumina tube) to prevent the seed crystal 305 from falling into the melt 304. Control of the temperature during the crystal growth process is important, especially at locations close to the seed and near the surface of the melt. In embodiments, the furnace may include multiple heater elements (e.g., resistive heaters) so that different amounts of heat can be applied across different multiple heating zones to achieve a desired temperature distribution within the melt. The temperature may be monitored at more than one location within the furnace using multiple temperature sensors 306. FIG. 3 depicts furnace 301 as having six temperature sensors, but this is merely for illustration purposes. An actual furnace may have more or fewer temperature sensors 306. In embodiments, the system 300 includes a controller 310. The controller 310 may include program instructions and memory configured to execute program instructions suitable for carrying out the thermal recipe for growing the cesium lithium borate crystals. In embodiments, the controller 310 is coupled to the one or more heating elements 307 and, thus, may control the temperature or other thermal properties of the corresponding one or more heating zones 309. In embodiments, the controller 310 may be programmed to maintain the melt at a temperature between about 800 °C and about 950 °C (e.g., above 850 °C) and maintain a region of the seed crystal between about 840 °C and about 860 °C during crystal growth. Seed crystal 305 and/or crucible 303 may be connected to one or more motors (not shown) so that one or both may be rotated during crystal growth. A stirring blade (not shown) may be used to help maintain the uniformity of the composition of the melt and promote more symmetric growth of the crystal. The controller 310 may be configured to control the one or more motors and/or the stirring blade. The controller 310 may execute or cause to execute any of other various method steps described throughout the present disclosure.

The melt 304 may be formed by combining and heating, for example, cesium carbonate (Cs₂CO₃), lithium carbonate (Li₂CO₃), boron trioxide (B₂O₃) or boric acid (H₃BO₃), and a source of chloride ions, such as cesium chloride (CsCl), lithium chloride (LiCl) or hydrochloric acid (a solution of HCl). A mixture of cesium carbonate, lithium carbonate and boron trioxide corresponding to stoichiometric CLBO has a mole ratio of 1:1:6 respectively of the starting materials. If boric acid is used instead of boron trioxide, then a mole ratio of 1:1:12 of cesium carbonate to lithium carbonate to boric acid would correspond to stoichiometric CLBO. Note that other compounds that provide sources of Cs, Li and B could be used when mixed in an appropriate ratio. For example, lithium oxide could be substituted for lithium carbonate, or cesium oxide could be substituted for cesium carbonate. The composition of the mixture should not deviate too far from the stoichiometric ratio else crystals of the wrong composition (such as lithium tetraborate or cesium triborate) may form inside, or instead of, the CLBO crystal. In one embodiment, less than 10% (for example 5% or 2.5%) of the boron precursor is replaced by a source of chloride ions. For example, a mixture of cesium carbonate, lithium carbonate, lithium chloride and boron trioxide in a mole ratio of 1.00:0.95:0.10:5.85 respectively could be used, where 2.5% of the boron precursor has been replaced by chloride ions. An equivalent mixture could be obtained by replacing some of the cesium carbonate by cesium chloride, as in a mixture of a mole ratio of 0.95:0.10:1.00:5.85 of cesium carbonate, cesium chloride, lithium carbonate and boron trioxide respectively. It is known that cesium may be lost (e.g. evaporate, or react with any oxygen or water in the gas above the melt) from the melt faster than other components, so, in one embodiment, the initial mix contains a small excess of cesium, for example a mixture of a mole ratio of 1.00:0.05:1.00:6.00 of cesium carbonate, cesium chloride, lithium carbonate and boron trioxide respectively. These are merely illustrations of how the ratios may be adjusted to incorporate chloride ions into the mixture and, optionally, to make other small adjustments to the component ratios. Many different compositions will achieve the desired result provided that the composition does not deviate from stoichiometric CLBO by too much, such as deviating from stoichiometry by less than 15%, by less than 10%, by less than 8%, by less than 5% or by less than 3%.

The components should be combined and heated prior to placing in the furnace. The components may be combined in aqueous solution or as a dry mixture. It is preferred to remove all gases (such as CO₂) and water prior to transferring to the furnace. The resulting mixture may be cooled to form a solid, for example a powder, prior to transferring to the furnace.

During crystal growth, the temperature of the bulk of the melt 304 should remain just above the melting point of CLBO, which is approximately 850°C. The temperature of the seed and the temperature near the surface of the melt 304 should be adjusted to achieve the desired crystal growth rate. B₂O₃ has a very high viscosity of approximately 35 Pa∙s near 850°C, which is detrimental to mixing and therefore crystal growth. CsCl and LiCl are salts with melting points of approximately 646°C and 610°C respectively. The viscosity of LiCl near 800°C is approximately 1 mPa∙s (similar to the viscosity of water at room temperature), i.e. about 4.5 orders of magnitude lower than that of B₂O₃ at this temperature. Because of its chemical similarity to LiCl, the viscosity of CsCl will be close to that of LiCl at temperatures well above their melting points. The melting point of CLBO is close to 850°C, therefore, Cl⁻ ions are ideal for incorporation into a flux for top-seeded solution growth of CLBO. This lower viscosity improves single crystal growth by efficiently replenishing depleted melt close to the surface of the growing crystal and improving temperature uniformity, which suppresses growth of other crystal phases. A Cl⁻ ion has a different number of valence shell electrons than the other atoms and ions in a CLBO crystal. A Cl⁻ ion has a slightly larger ionic radius than Cs⁺. These factors and its negative charge should result in negligible incorporation of Cl into the CLBO crystal. Furthermore alkali-metal chlorides, such as LiCl and CsCl, are strongly hygroscopic and will attract water molecules away from CLBO aiding in reducing the water content of the final CLBO crystal.

Seed crystal 305 may comprise a single high-quality CLBO crystal.

Although the present crystal growth method is described herein using various temperatures, pressures, melt stoichiometries, furnace types, crucible sizes, crucible and crystal rotation rates, unless otherwise specified in the appended claims, other temperatures, pressures, melt stoichiometries, furnace types, crucible sizes, and crucible and crystal rotation rates are considered within the scope of this invention.

Few nonlinear crystals with good transmission and high damage threshold below 200 nm wavelength are commercially available. In particular, there is no prior art for mass-producing CLBO crystals larger than 350 g with high purity, high damage threshold, high nonlinear coefficient, and high transparency in the sub-200 nm region. The embodiments of the present method provide a lower viscosity melt for CLBO growth enabling larger, higher purity boule formation. The present growth method additionally uses a melt composition without fluorine, and therefore is relatively easier and less expensive than methods that include the use of fluoride ions or fluorine.

One skilled in the appropriate arts will readily appreciate that there are many possible applications of the inventive laser crystal growth methods described herein in addition to their use in semiconductor inspection and metrology. For example, a laser incorporating a CLBO crystal grown according to the present method and operating at a wavelength close to 193.4 nm can be used in a lithography system configured to expose patterns into photoresist coated on a substrate such as a semiconductor wafer. In another example, a laser incorporating a CLBO crystal grown according to the present method and operating at a wavelength between about 180nm and 200nm may be used in a system configured to cut or ablate biological tissue. Although the present disclosure has been described with respect to certain specific embodiments, it will be clear to those skilled in the art that the inventive features of the present disclosure are applicable to other embodiments as well, all of which are intended to fall within the scope of the present disclosure.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The description is presented to enable one of ordinary skill in the art to make and use the disclosure as provided in the context of a particular application and its requirements. As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the preferred embodiment will be apparent to those with skill in the art, and the general principles defined herein may be applied to other embodiments. Therefore, the present disclosure is not intended to be limited to the particular embodiments shown and described but is to be accorded the widest scope consistent with the principles and novel features herein disclosed.

Furthermore, it is to be understood that the invention is defined by the appended claims. It will be understood by those within the art that, in general, terms used herein, and especially in the appended claims (e.g., bodies of the appended claims) are generally intended as "open" terms (e.g., the term "including" should be interpreted as "including but not limited to," the term "having" should be interpreted as "having at least," the term "includes" should be interpreted as "includes but is not limited to," and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases "at least one" and "one or more" to introduce claim recitations. However, the use of such phrases should not be construed to imply that the introduction of a claim recitation by the indefinite articles "a" or "an" limits any particular claim containing such introduced claim recitation to inventions containing only one such recitation, even when the same claim includes the introductory phrases "one or more" or "at least one" and indefinite articles such as "a" or "an" (e.g., "a" and/or "an" should typically be interpreted to mean "at least one" or "one or more"); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of "two recitations," without other modifiers, typically means at least two recitations, or two or more recitations). Furthermore, in those instances where a convention analogous to "at least one of A, B, and C, and the like" is used, in general such a construction is intended in the sense one having skill in the art would understand the convention (e.g., "a system having at least one of A, B, and C" would include but not be limited to systems that have A alone, B alone, C alone, A and B together, A and C together, B and C together, and/or A, B, and C together, and the like). In those instances where a convention analogous to "at least one of A, B, or C, and the like" is used, in general such a construction is intended in the sense one having skill in the art would understand the convention (e.g., "a system having at least one of A, B, or C" would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase "A or B" will be understood to include the possibilities of "A" or "B" or "A and B."

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed is:

1. A method of manufacturing a cesium lithium borate crystal comprising:
forming a material comprising Cs, Li, B, O, and Cl;
heating the material to form a melt;
controlling a temperature of the melt;
lowering a seed crystal into the melt, and
adjusting the temperature of the melt to grow a cesium lithium borate crystal.

2. The method of manufacturing a crystal according to claim 1, wherein adjusting the temperature to grow the cesium lithium borate crystal includes maintaining the seed crystal at a temperature within a range of 840°C to 860°C during growth of the crystal.

3. The method of manufacturing a crystal according to claim 1, wherein a source of the Cl comprises at least one of LiCl or CsCl.

4. The method of manufacturing a crystal according to claim 3, wherein the melt comprises approximately between 0.1 and 10 mole-percent Cl.

5. The method of manufacturing a crystal according to claim 4, wherein the melt comprises approximately between 5 and 6 mole-percent Cs.

6. The method of manufacturing a crystal according to claim 4, wherein the melt comprises approximately between 27 and 37 mole-percent B.

7. The method of manufacturing a crystal according to claim 1, further comprising growing the cesium lithium borate crystal by a top-seeded solution method.

8. The method of manufacturing a crystal according to claim 1, further comprising growing the cesium lithium borate crystal by a flux method.

9. The method of manufacturing a crystal according to claim 1, further comprising growing the cesium lithium borate crystal by a melt method.

10. The method of manufacturing a crystal according to claim 1, wherein forming the material includes heating the material to a temperature between 800°C and 950°C.

11. A frequency conversion apparatus which contains a crystal manufactured according to the method of claim 1.

12. A laser configured to generate a wavelength between 185 nm and 300 nm, the laser including a frequency conversion apparatus according to claim 11.

13. The laser of claim 12, the laser further including a second frequency conversion apparatus.

14. A system for inspecting or measuring a sample, the system comprising:
an illumination source configured to generate illumination having a wavelength between 185 nm and 300 nm;
an optical sub-system configured to direct the illumination from the illumination source onto a sample and collect illumination reflected from, scattered by and/or transmitted through the sample and direct it to a sensor; and
a controller connected to the sensor and configured to analyze data collected by the sensor,
wherein the illumination source includes a laser according to claim 13.

15. A system for growing a cesium lithium borate crystal comprising:
a crucible configured to contain a melt comprising cesium, lithium, boron, oxygen, and chloride ions;
a seed holder configured to position a seed crystal in the melt;
one or more heating elements configured to control a temperature of the melt and the seed crystal; and
a controller configured to maintain the melt at a temperature above 850°C and the seed crystal at a temperature within a range of 840°C to 860°C during growth of the crystal.

16-016. A cesium lithium borate single crystal, wherein the single crystal is grown from a melt comprising cesium, lithium, boron, oxygen, and between about 0.1 mole-percent and about 10 mole-percent chloride ions, and wherein the single crystal has a hydroxyl impurity content and a crystallographic defect density that are each lower than those of cesium lithium borate single crystals grown from melts that are free of chloride ions.
